(19) United States
(12) Patent Application Publication
(10) Pub. No.: US 2009/0097199 A1
(43) Pub. Date: Apr. 16, 2009

(54) PORTABLE ELECTRONIC DEVICE INSTALLED WITH DATA CABLE

(75) Inventor: PI-FENG SHIH, Tu-Cheng (TW)

Correspondence Address: PCE INDUSTRY, INC.;ATT. Steven Reiss, 458 E. LAMBERT ROAD, FULLERTON, CA, 92835, US

(73) Assignee: CHI MEI COMMUNICATION SYSTEMS, INC., Tu-Cheng City (TW)

(21) Appl. No.: 11/964,856

(22) Filed: Dec. 27, 2007

(30) Foreign Application Priority Data
Oct. 12, 2007 (CN) 200710202033.4

(51) Int. Cl. H05K 7/00; G06F 1/16

(52) U.S. Cl. 361/679.55

(57) ABSTRACT

A portable electronic device (10) includes a data cable (105) and a housing (101). The data cable is configured to receive or transfer data. The housing includes a receiving portion (103) formed therein; the receiving portion is configured for receiving the data cable.

### BACKGROUND OF THE INVENTION

1. Field of the Invention

The present invention generally relates to a portable electronic device, particularly to a portable electronic device installed with a data cable.

2. Description of Related Art

Nowadays, portable electronic device, such as mobile phones and personal digital assistants (PDAs), are widely used. In use, portable electronic devices often need to be electronically connected to other electronic devices to receive or transfer data. Generally, a data cable is used to connect the electronic devices with each other for receiving and transferring data.

Since most electronic devices are not configured with an integrated data cable, data cables that connect the portable electronic devices have to be separately prepared. Thus, the data cable may easily be lost.

Therefore, a new portable electronic device is desired in order to overcome the above-described shortcomings.

### SUMMARY OF THE INVENTION

A portable electronic device includes a data cable and a housing. The data cable is configured to receive or transfer data. The housing includes a receiving portion formed therein; the receiving portion is configured for receiving the data cable.

Other novel features will become more apparent from the following detailed description when taken in conjunction with the accompanying drawings.

### BRIEF DESCRIPTION OF THE DRAWINGS

Many aspects of the portable electronic device can be better understood with reference to the following drawings. The components in the drawings are not necessarily drawn to scale, the emphasis instead being placed upon clearly illustrating the principles of the portable electronic device. Moreover, in the drawings, like reference numerals designate corresponding parts throughout the several views.

FIG. 1 is a schematic view of a portable electronic device in accordance with a first embodiment.

FIG. 2 is a schematic view of a portable electronic device in accordance with a second embodiment.

FIG. 3 is a schematic view of a data cable contained in the portable electronic device shown in FIG. 2.

FIG. 4 is a schematic view of the data cable extending from the portable electronic device shown in FIG. 2.

### DETAILED DESCRIPTION OF THE INVENTION

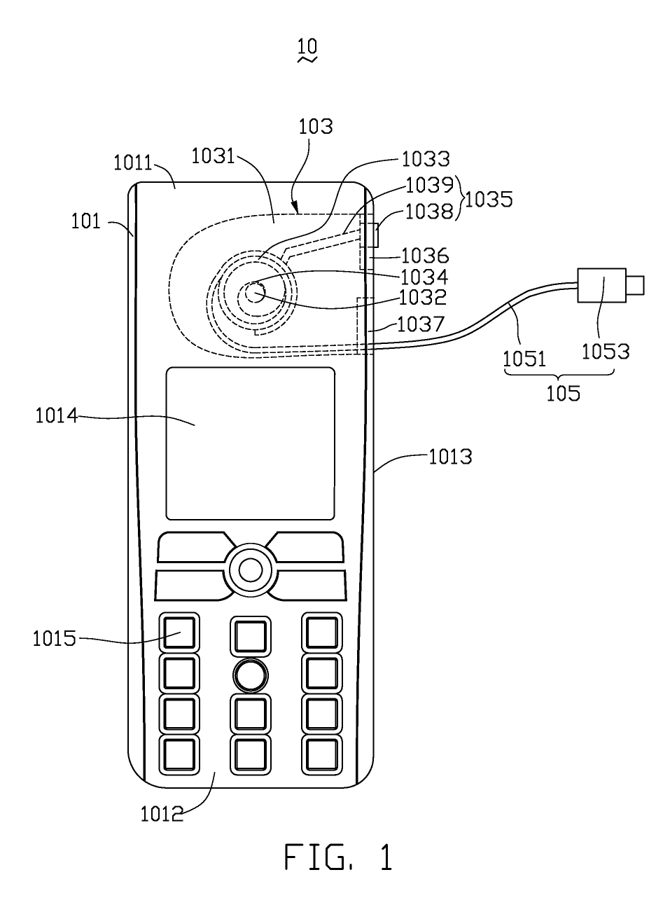

Referring to FIG. 1, a portable electronic device 10 in accordance with a first embodiment is provided. The portable electronic device 10 is a mobile phone including a housing 101, a circuit board (not shown) received in the housing 101, and a data cable 105 electronically connected to the circuit board.

The housing 101 includes a top end 1011, a bottom end 1012 opposing to the top end 1011 and a side wall 1013 connecting the top end 1011 with the bottom end 1012. A display 1014 is mounted on a middle portion of the housing 101, and a keypad 1015 is mounted on the housing 101 and positioned adjacent to the bottom end 1012.

The housing 101 also includes a receiving portion 103 formed therein; the receiving portion 103 is configured to receive the data cable 105. The receiving portion 103 includes a receiving groove 1031, a shaft 1032, a barrel 1033, a spring 1034, a button 1035, a first aperture 1036 configured for installing the button 1035 and a second aperture 1037 adjacent to the first aperture 1036.

The housing 101 defines the receiving groove 1031 therein. The shaft 1032 is installed in the receiving groove 1031, and two ends of the shaft 1032 are fixed on the housing 101. The barrel 1033 is configured to coil around the data cable 105 thereon and rotatably placed over the shaft 1032. The spring 1034 is a torsion spring coiled around the shaft 1032, and has one end fixed on the shaft 1032 and another end of the spring 1034 fixed on the barrel 1033. The first aperture 1036 is defined in the side wall 1013 and communicates with the receiving groove 1031. The button 1035 includes an operating portion 1038 and a holding portion 1039 for resisting the data cable 105 coiled around the barrel 1033. The operating portion 1038 is a block movably received in the first aperture 1036. The holding portion 1039 is a bar having an end connected to the operating portion 1038. When the operating portion 1038 is pressed into the first aperture 1036, an end of the holding portion 1039 is pressed towards the barrel 1033. The second aperture 1037 is defined in the side wall 1013 and communicates with the receiving groove 1031.

The data cable 105 includes a wire portion 1051 and a connector 1053. The wire portion 1051 is a conductive wire covered with plastic material. The connector 1053 can be a USB (Universal Serial Bus) connector or a Mini-USB connector, etc. The wire portion 1051 is coiled around the barrel 1033, one end of the wire portion 1051 is electronically connected to the circuit board, another end of the wire portion 1051 extends out the housing 101 from the second aperture 1037 and is connected to the connector 1053. The connector 1053 is received in the second aperture 1037.

In assembly, the spring 1034 is coiled around the shaft 1032. The barrel 1033 is placed over the shaft 1032, one end of the spring 1034 is fixed on the shaft 1032, and another end of the spring 1034 is fixed on the barrel 1033. The shaft 1032, the barrel 1033 and the spring 1034 are then received in the receiving groove 1031; at least one end of the shaft 1032 is fixed on the housing 101. The data cable 105 is coiled around the barrel 1033; one end of the wire portion 1051 is electronically connected to the circuit board, another end of the wire portion 1051 extends out from the second aperture 1037 of the housing 101 and is connected to the connector 1053.

In use, when the portable electronic device 10 needs to be connected to other electronic devices for receiving or transferring data, the data cable 105 is pulled out from the second aperture 1037. When the data cable 105 is pulled, the barrel 1033 is rotated, and the spring 1034 is bent to accumulate potential energy. The operating portion 1038 is then pressed and held by typical apparatuses (not shown), thus the holding portion 1039 presses the data cable 105 on the barrel 1033 to hold the extending data cable 105. In this way, the circuit board can be easily connected to other electronic devices to receive or transfer data via the data cable 105. When the extending data cable 105 requires to be received into the housing 101, the held operating portion 1038 is released. The spring 1034 resiles to drive the barrel 1033 to rotate, thus the data cable 105 is coiled around the barrel 1033 and received into the housing 101.

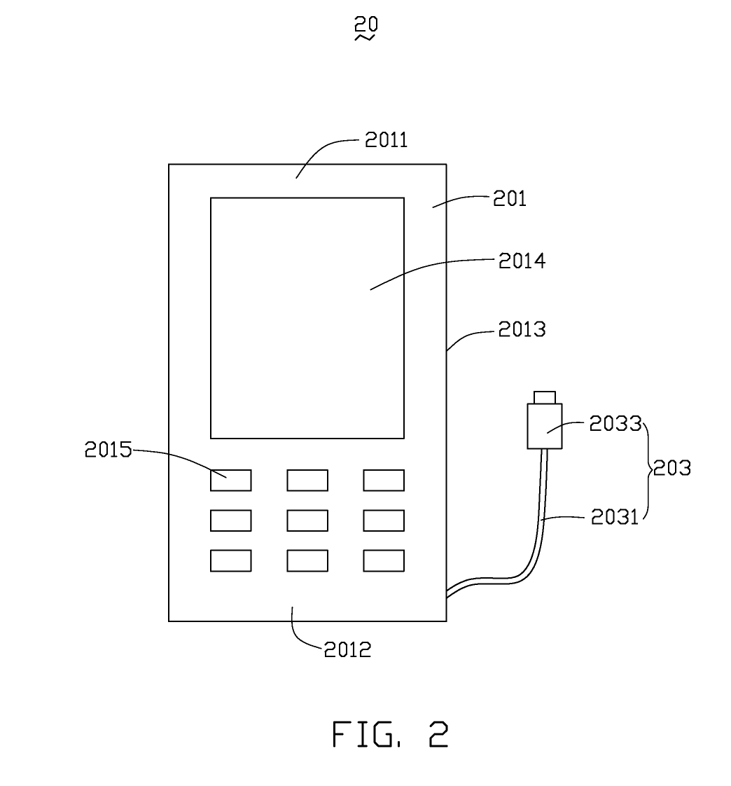

Referring to FIG. 2, a portable electronic device 20 in accordance with a second embodiment is provided. The portable electronic device 20 is a mobile phone including a housing 201, a circuit board (not shown) mounted in the housing 201 and a data cable 203 electronically connected to the circuit board.

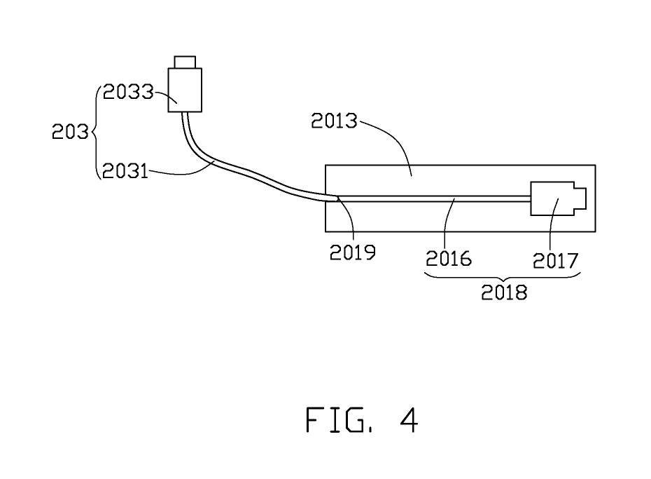

Similarly to the housing 101 of the portable electronic device 10, the housing 201 includes a top end 2011, a bottom end 2012 and a side wall 2013. A display 2014 is mounted on a middle portion of the housing 201, and a keypad 2015 is mounted on the housing 201 and positioned to be adjacent to the bottom end 2012. Also referring to FIG. 4, the housing 201 defines a wire groove 2016, a connector groove 2017 communicates with one end of the wire groove 2016 and a through hole 2019 communicated with another end of the wire groove 2016 therein. The wire groove 2016 and the connector groove 2017 incorporate as a receiving portion 2018.

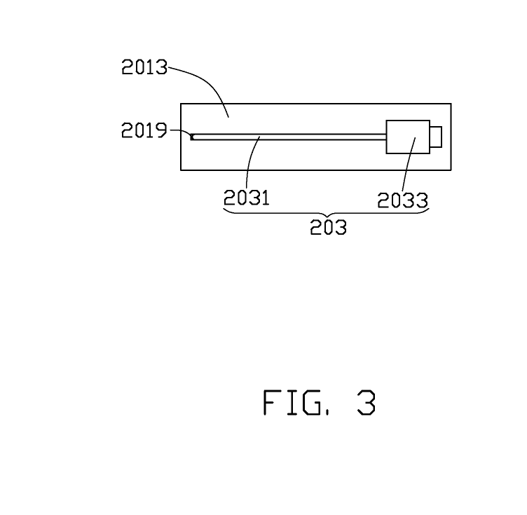

Similarly to the data cable 105 of the portable electronic device 10, the data cable 203 includes a wire portion 2031 corresponding to the wire groove 2016 and a connector 2033 corresponding to the connector groove 2017. One end of the wire portion 2031 is electronically connected to the circuit board, and another end of the wire portion 2031 extends out from the through hole 2019 and is connected to the connector 2033. Also referring to FIG. 3, the wire portion 2031 can be received in the wire groove 2016, and the connector 2033 can be received in the connector groove 2017. Also referring to FIG. 4, in use, the data cable 203 is taken out from the wire groove 2016 and the connector groove 2017 allowing the connector to connect to electronic devices to receive or transfer data.

Understandably, in the portable electronic devices 10/20, the data cable 105/203 can be received in the housings 101/201 to miniaturize the portable electronic device 10/20. Furthermore, unlike additional data cables of typical portable electronic devices, in use, the attached data cables 105/203 are configured to be received within the portable electronic device, thus prevent it from being lost.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A portable electronic device, comprising:
a data cable configured to receive or transfer data; and
a housing including a receiving portion formed therein, the receiving portion being configured for receiving the data cable.

2. The portable electronic device as claimed in claim 1, wherein the receiving portion includes a receiving groove defined in the housing and configured for receiving the data cable.

3. The portable electronic device as claimed in claim 2, wherein the receiving portion includes a shaft installed in the receiving groove and a barrel rotatably placed over the shaft, the data cable being coiled around the barrel.

4. The portable electronic device as claimed in claim 3, wherein the receiving portion includes a spring which is a torsion spring coiled around the shaft, one end of the spring being fixed on the shaft, and another end of the spring being fixed on the barrel.

5. The portable electronic device as claimed in claim 4, wherein the housing defines a first aperture communicating with the receiving groove therein and the receiving portion includes a button, the button including an operating portion and a holding portion, the operating portion being movably received in the first aperture, the holding portion being connected to the operating portion.

6. The portable electronic device as claimed in claim 5, wherein the housing defines a second aperture communicating with the receiving groove therein, the data cable including a wire portion coiled around the barrel and a connector received in the second aperture.

7. The portable electronic device as claimed in claim 1, wherein the receiving portion includes a wire groove defined in the housing and a connector groove defined in the housing and communicating with one end of the wire groove.

8. The portable electronic device as claimed in claim 7, wherein the data cable includes a wire portion corresponding to the wire groove and a connector corresponding to the connector groove, the wire portion being received in the wire groove, and the connector being received in the connector groove.
